(19) United States
(12) Patent Application Publication
(10) Pub. No.: US 2026/0245194 A1
(43) Pub. Date: Aug. 20, 2026

(54) Device Management System and Device Management Method

(71) Applicant: Hitachi High-Tech Corporation, Minato-ku, Tokyo (JP)

(72) Inventors: Naoya TANAHASHI, Tokyo (JP); Shintaro TAKADA, Tokyo (JP); Fumihiro SASAJIMA, Tokyo (JP)

(21) Appl. No.: 19/165,209

(22) PCT Filed: May 18, 2023
(86) PCT No.: PCT/JP2023/018661

§ 371 Date: Sep. 15, 2025

(51) Int. Cl. G06T 7/00; H01J 37/28

(52) U.S. Cl. CPC G06T 7/0004; H01J 37/28; G06T 2207/20081; G06T 2207/30148

(57) ABSTRACT

A system for managing a device that captures an image of a wafer and outputs a critical dimension value of a pattern includes an indicator value prediction model generation unit configured to generate, using training data including first and second training datasets, a model that outputs a predicted indicator value of received image data. The first training dataset is generated by associating the same first indicator value with a plurality of pieces of first image data obtained by capturing images of a first wafer with devices in a first device group where a critical dimension value difference for the same wafer is equal to or less than a predetermined reference value, the devices in the first device group are adjusted such that an indicator value is changed by a predetermined value from the first indicator value, and then the second training dataset is generated by associating a second indicator value, which is a value changed by the predetermined value from the first indicator value, with a plurality of pieces of second image data obtained by capturing images of the first wafer with the devices after adjustment. Accordingly, a plurality of devices can be managed without being affected by an individual difference among the devices.

### TECHNICAL FIELD

The present invention relates to a device management system and a device management method.

### BACKGROUND ART

With miniaturization of a pattern formed on a semiconductor wafer, dimension measurement with higher measurement accuracy is required in a semiconductor production step. The requirement for the measurement accuracy extends not only to improving measurement accuracy of a measurement device alone, but also to reducing a measurement dimension difference among a plurality of devices on a production line and to reducing a measurement dimension fluctuation due to a change over time in a device.

In order to measure a width of a fine pattern on the nanometer order, a critical-dimension SEM, which is a pattern width measurement scanning electron microscope that can enlarge and capture an image of the pattern, has been used. In such a scanning electron microscope device, in order to reduce a measurement dimension difference among a plurality of devices placed on a production line, a method of performing adjustment by analyzing a device variation factor thereof based on data captured at the time of measurement has been attempted.

PTL 1 discloses a system for managing a device variation, which is a measurement dimension difference among a plurality of scanning electron microscope devices, for the purpose of reducing a device variation among the plurality of devices or a device variation due to a change over time. Specifically, PTL 1 discloses that “a system and a method thereof for managing a device variation among devices and a device variation due to a change over time in a scanning electron microscope device includes: measurement units 10, 301a, 301b; 18, 301 a that measure the device variation among devices or due to a change over time based on secondary electron image data obtained by capturing an image of a standard wafer and measure an indicator value indicating various device states substantially at the same time, device variation factor analysis units 301c and 301e that analyze a relationship between the device variation measured by the measurement units and the indicator value indicating the various device states to estimate a device variation occurrence factor, and an output unit 302 that displays and outputs the device variation occurrence factor estimated by the device variation factor analysis unit”.

### CITATION LIST

### Patent Literature

PTL 1: JP2007-122995A

### SUMMARY OF INVENTION

### Technical Problem

In the invention disclosed in PTL 1, in the scanning electron microscope device, an image feature is directly calculated based on acquired data, and a relationship between the device variation and the feature is analyzed to estimate the device variation factor.

However, the above technique does not consider an influence of an individual difference among a plurality of devices. Here, the individual difference is assumed to be a difference in hardware appearing among the devices, and is assumed to be a difference in a composite state such as blurring, brightness, or sharpness appearing in images captured by the devices. When a feature is extracted from an image without considering such an individual difference, a feature having a variable distribution different among the devices due to the individual difference is extracted as the device variation factor. Since the device variation is not eliminated even when this feature is adjusted, there is a concern that a time required to reduce the measurement dimension difference may be prolonged.

The invention has been made in view of the above circumstances, and an object thereof is to manage a plurality of devices without being affected by an individual difference among the devices and to contribute to improvement in device variation factor analysis accuracy.

### Solution to Problem

In order to achieve the above object, a representative device management system according to the invention is a device management system for managing a device that captures an image of a wafer and outputs a critical dimension value of a pattern, the device management system including: a training data generation unit configured to generate training data including a first training dataset and a second training dataset; and an indicator value prediction model generation unit configured to generate, using the first training dataset and the second training dataset, an indicator value prediction model that outputs a predicted indicator value for a predetermined indicator indicating a state of received image data, in which the training data generation unit generates the first training dataset by associating a same first indicator value with a plurality of pieces of first image data obtained by capturing images of a first wafer with devices in a first device group where a critical dimension value difference for a same wafer is equal to or less than a predetermined reference value, and adjusts the devices in the first device group such that an indicator value is changed by a predetermined value from the first indicator value, and then generates the second training dataset by associating a second indicator value, which is a value changed by the predetermined value from the first indicator value, with a plurality of pieces of second image data obtained by capturing images of the first wafer with the devices after adjustment.

In addition, a representative device management method according to the invention is a device management method for managing a device that captures an image of a wafer and outputs a critical dimension value of a pattern, the device management method including: causing a device management system to execute a training data generation step of generating training data including a first training dataset and a second training dataset, and an indicator value prediction model generation step of generating, using the first training dataset and the second training dataset, an indicator value prediction model that outputs a predicted indicator value for a predetermined indicator indicating a state of received image data, in which the training data generation step includes generating the first training dataset by associating a same first indicator value with a plurality of pieces of first image data obtained by capturing images of a first wafer with devices in a first device group where a critical dimension value difference for a same wafer is equal to or less than a predetermined reference value, and adjusting the devices in the first device group such that an indicator value is changed by a predetermined value from the first indicator value, and then generating the second training dataset by associating a second indicator value, which is a value changed by the predetermined value from the first indicator value, with a plurality of pieces of second image data obtained by capturing images of the first wafer with the devices after adjustment.

### Advantageous Effects of Invention

According to the invention, a plurality of devices can be managed without being affected by an individual difference among the devices.

### BRIEF DESCRIPTION OF DRAWINGS

FIG. 1 is a block diagram showing an example of a configuration of a device variation factor analysis device and a device variation factor analysis system including a device management method according to a first embodiment.

FIG. 2 is a flowchart showing an example of a method for generating training data to be stored in a training data storage unit in the device variation factor analysis device according to the first embodiment.

FIG. 3 shows an example of an image obtained by capturing a line pattern.

FIG. 4 is a diagram showing an example of a histogram of noise values calculated based on images captured by two different devices having an individual difference.

FIG. 5 shows an example of data where image data is associated with a corrected indicator value.

FIG. 6 shows an example of data where the image data is associated with the indicator value after adjustment.

FIG. 7 is a flowchart showing an example of processing in a device variation factor analysis unit in the device variation factor analysis device according to the first embodiment.

FIG. 8 is a diagram showing an example of a data structure stored in an analysis data storage unit in the device variation factor analysis device according to the first embodiment.

FIG. 9 shows an example of a data structure of predicted indicator value data stored in an analysis result storage unit by the device variation factor analysis unit.

FIG. 10 is a flowchart showing an example of processing in a device variation determination unit in the device variation factor analysis device.

FIG. 11 shows an example of a data structure stored in the analysis result storage unit by the device variation determination unit.

FIG. 12 is a diagram showing an example of an output screen output to an input and output device by execution of the device variation factor analysis device according to the first embodiment.

FIG. 13 is a flowchart showing an example of processing in an analysis result processing unit in the device variation factor analysis device according to the first embodiment.

FIG. 14 is a block diagram showing an example of a configuration of a device variation factor analysis device and a device variation factor analysis system including a device management method according to a second embodiment.

FIG. 15 shows an example of data where image data, an indicator value, and an actually measured critical dimension value are associated.

FIG. 16 is a flowchart showing an example of processing in a device variation factor analysis unit in the device variation factor analysis device according to the second embodiment.

FIG. 17 shows an example of a structure of predicted critical dimension value data stored in an analysis result storage unit by the device variation factor analysis unit.

FIG. 18 is a diagram showing an example of an output screen output to an input and output device by execution of the device variation factor analysis device according to the second embodiment.

FIG. 19 is a block diagram showing an example of a configuration of a device variation factor analysis device and a device variation factor analysis system including a device management method according to a third embodiment.

FIG. 20 is a flowchart showing an example of processing in a device variation factor analysis unit in the device variation factor analysis device according to the third embodiment.

FIG. 21 is a flowchart showing an example of processing in a critical dimension value prediction model generation unit in the device variation factor analysis device according to the third embodiment.

FIG. 22 shows an example of a structure of data stored in a history information storage unit.

FIG. 23 shows an example of a structure of data extracted by the critical dimension value prediction model generation unit.

FIG. 24 is a flowchart showing an example of processing in a device variation factor analysis unit in a device variation factor analysis device according to a fifth embodiment.

FIG. 25 shows an example of a structure of device variation factor history data stored in an analysis result storage unit.

FIG. 26 shows an example of a structure of data stored in the analysis result storage unit by the device variation factor analysis unit according to the fifth embodiment.

### DESCRIPTION OF EMBODIMENTS

Hereinafter, embodiments of the invention will be described with reference to the drawings.

### First Embodiment

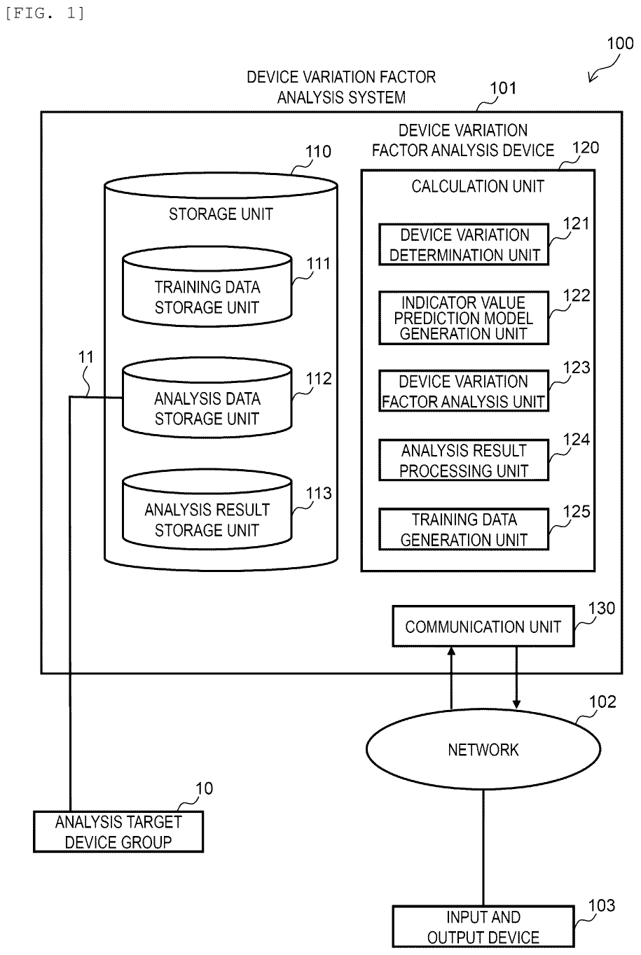

FIG. 1 shows a device variation factor analysis device 101 and a device variation factor analysis system 100 including a device management method according to an embodiment of the invention.

The device variation factor analysis system 100 of the embodiment includes the device variation factor analysis device 101 and an input and output device 103 used by a user, which are communicably connected via a network 102.

The network 102 enables the input and output device 103 and the device variation factor analysis device 101 to communicate with each other.

The input and output device 103 is an information processing device such as a personal computer (PC). The user inputs predetermined information to the input and output device, and the input and output device outputs a result calculated in the device variation factor analysis device 101. As a specific example, when it is desired to analyze a device variation factor of two devices in a certain device group, input information is device numbers to be compared, and output information is a variable that is a device variation factor candidate.

The device variation factor analysis device 101 is a device variation factor analysis device that generates an indicator value prediction model for predicting a value of an indicator value from an image based on a dataset where an image captured by a scanning electron microscope is associated with an indicator value from which an individual difference is removed, and analyzes a device variation factor in a certain device group based on this model.

The device variation factor analysis device 101 includes a storage unit 110 and a calculation unit 120.

The storage unit 110 includes a training data storage unit 111 that stores image data and indicator value information to be used as training data for constructing the indicator value prediction model, an analysis data storage unit 112 that stores data to be used for analysis acquired from an analysis target device group 10, and an analysis result storage unit 113 that stores a result calculated by device variation factor analysis.

The training data storage unit 111 can transmit and receive data to and from the analysis target device 10 via a data bus or the Internet 11.

The calculation unit 120 includes a device variation determination unit 121 that calculates a critical dimension value difference based on data acquired from the analysis target device group 10 and calculates a device variation magnitude, an indicator value prediction model generation unit 122 that constructs the indicator value prediction model based on the training data, a device variation factor analysis unit 123 that analyzes a device variation factor by applying the indicator value prediction model to the analysis target device group, an analysis result processing unit 124 for calculating a result of comparing analyzed results among devices, and a training data generation unit 125 that generates the training data.

A communication unit 130 communicates with the device variation factor analysis device 101 and other devices via the network 102.

In the embodiment, two devices are assumed as the analysis target device group 10, and device numbers thereof are a device A and a device B, respectively. In particular, in the embodiment, it is assumed that a device state of the device B fluctuates and a critical dimension value fluctuation of 0.5 nm occurs. That is, it is assumed that device variation factor analysis is performed on the device A that is a normal device and the device B that is a device having a device variation. Here, the device having a device variation is a device having a device variation equal to or greater than a threshold value.

Here, the number of devices in the analysis target device group 10 may be more than two. In this case, the number of devices to which the indicator value prediction model to be described later is applied may be increased according to the number of devices in the analysis target device group.

In the embodiment, it is assumed that the training data storage unit 111 stores data acquired from the analysis target device group 10.

Here, a part of data of devices not contained in the analysis target device group 10 or only a device group not contained in the analysis target device group 10 may be stored in the training data storage unit 111.

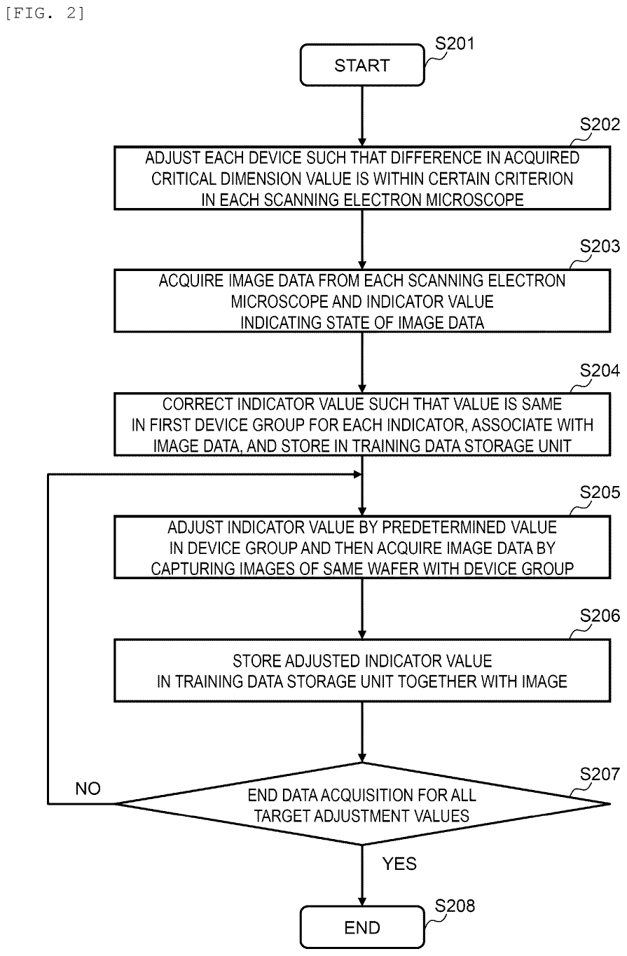

FIG. 2 shows a flow for creating the data to be stored in the training data storage unit 111. In the following embodiment, an example of a method for creating the data to be stored in the training data storage unit 111 will be described according to this flow.

In the embodiment, a device group stored in the training data storage unit 111 is referred to as a first device group. After the processing is started (step S1), first, in step S202, the training data generation unit 125 adjusts each device such that a difference in an acquired critical dimension value is within a certain criterion in each scanning electron microscope in the first device group.

Here, the criterion of the certain critical dimension value difference is as desired. However, in order to create a dataset where an influence of an individual difference is removed with reference to a device state set here, it is desirable to set the criterion within a critical dimension value difference regarded as a device variation. In the embodiment, as the criterion of the device variation, a magnitude of the critical dimension value difference from a critical dimension value of the device A is in a range of −0.1 nm to +0.1 nm.

This criterion may be appropriately changed, such as whether a difference from a maximum value of critical dimension values acquired by the first device group or a difference from an average value of the critical dimension values acquired by the first device group is within a certain range.

It is also desirable that a dimension measurement pattern of a standard wafer that is a critical dimension measurement target is a pattern that has a fairly sharp edge and is sensitive enough to respond to a slight difference in the device state to cause a change in the critical dimension value.

The standard wafer that is the critical dimension measurement target is desirably equivalent to a wafer used in device variation factor analysis. If a design dimension or a pattern type differs, accuracy of the generated indicator value prediction model may decrease.

Further, it is desirable that the standard wafer that is the critical dimension measurement target has a small pattern dimension variation on the same wafer. This is because, in order to prevent an influence of critical dimension value shape dependency due to a rare wafer shape deformation, critical dimension values at a plurality of locations are generally acquired by the same device, and an average value thereof is often used as a representative critical dimension value in each device.

In this embodiment, the dimension measurement pattern of the target standard wafer is assumed to be a linear pattern having a fairly sharp edge, which is called a line pattern.

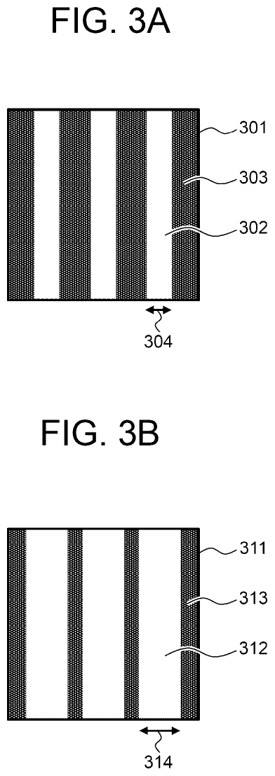

FIG. 3(a) shows an example of an image acquired by capturing the line pattern. A white line 302 in a captured image 301 is the pattern, and a scanning electron microscope can measure a length of a pattern width 304. A surrounding gray portion 303 is a wafer surface.

As a device adjustment method, it is assumed that a device control parameter is appropriately adjusted, such as an electron beam focus position and a retarding voltage for adjusting an acceleration voltage of an electron beam in the vicinity of the wafer. Since a state of the captured image is changed by this operation, an acquired critical dimension value is changed.

Next, in step S203, the training data generation unit 125 acquires image data obtained by capturing images of the pattern on the target standard wafer by the first device group, and then acquires an indicator value that may be a device variation factor indicating a state of the image data from each device.

In the embodiment, a tilt angle indicator representing an electron beam angle, a contrast indicator representing brightness and darkness contrast of the image, and a noise indicator quantifying an amount of noise contained in the image are assumed as indicator values. The contrast indicator and the noise indicator can be calculated based on the captured image. The tilt angle indicator may be calculated based on the captured image or may be acquired based on a setting value at the time of imaging.

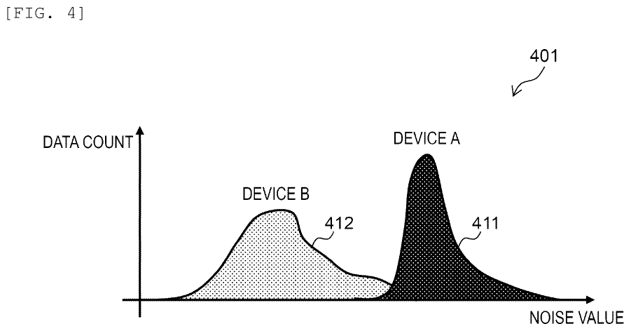

FIG. 4 shows a histogram 401 of noise values calculated based on images captured by the device A and the device B. When there is an individual difference in the device group, even when the critical dimension value difference is within the criterion, a difference may occur in the indicator value as in the histogram 411 of the device A and the histogram 412 of the device B. When such an indicator value is directly used, this variable may be extracted as the device variation factor.

Therefore, in step S204, first, the training data generation unit 125 corrects each acquired indicator value such that the value is the same in the first device group in order to remove the influence of the individual difference as shown in FIG. 4. In this embodiment, the value of each indicator value is corrected to 0. Accordingly, it is possible to create a dataset where an influence of an indicator value difference due to the individual difference appearing between the devices is removed. In addition, by constructing the indicator value prediction model based on this dataset and using the indicator value prediction model for device variation factor analysis, it is possible to perform device variation factor analysis from which the influence of the individual difference in the device group is removed.

Thereafter, in step S204, the image data and the corrected indicator value are associated and stored in the training data storage unit 111. Here, processing corresponding to the indicator value correction is not performed for the image data.

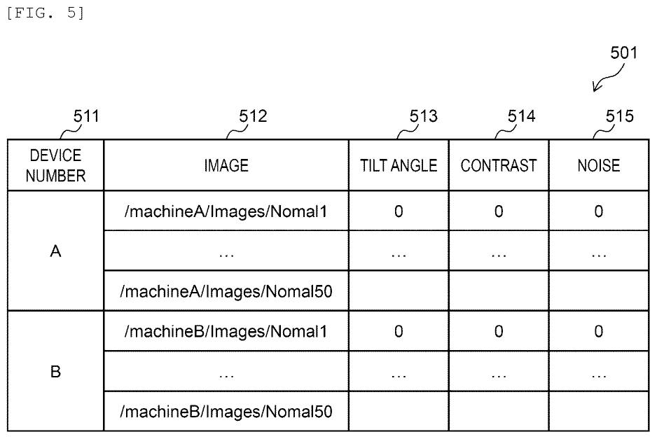

FIG. 5 shows an example of the dataset where the image data and the corrected indicator value are associated.

A dataset 501 where the image data and the corrected indicator value are associated includes a device number 511, a path 512 to the image data, a tilt angle 513 that is an analysis target indicator value, contrast 514, and noise 515. Here, the corrected value 0 as described above is stored in the tilt angle 513, the contrast 514, and the noise 515.

In FIG. 5, each device obtains the image data from a plurality of portions of one wafer.

Here, a different corrected indicator value may be stored for each image. For example, each indicator value in each device may be standardized such that an average value is 0 and a standard deviation is 1.

Next, in step S205, the training data generation unit 125 adjusts the devices such that the image indicator value is changed by a predetermined value in the first device group, and then acquires image data by capturing images of the same wafer.

Here, the predetermined adjustment value can be determined as desired. In the embodiment, four adjustment values of +100, −100, +50, and −50 are assumed for each indicator value.

As the number of types of the adjustment values increases, the number of pieces of training data used for generating the indicator value prediction model to be described later increases, and thus it can be expected that a more accurate prediction model is constructed.

In the embodiment, first, it is assumed that the noise indicator value is adjusted by +50 for each device. The noise indicator value is adjusted by adjusting an aperture size, adjusting an image processing parameter, or the like.

FIG. 3(b) shows an example of an image acquired by capturing the line pattern after the device state is adjusted. A white line 312 of a captured image 311 is the pattern, and a length of a pattern width 314 is measured by the scanning electron microscope. A surrounding gray portion 313 is the wafer surface. It is assumed that the image is distorted due to noise, the width 314, which is a critical dimension value portion, increases, and an acquired critical dimension value increases, as compared to FIG. 3(a).

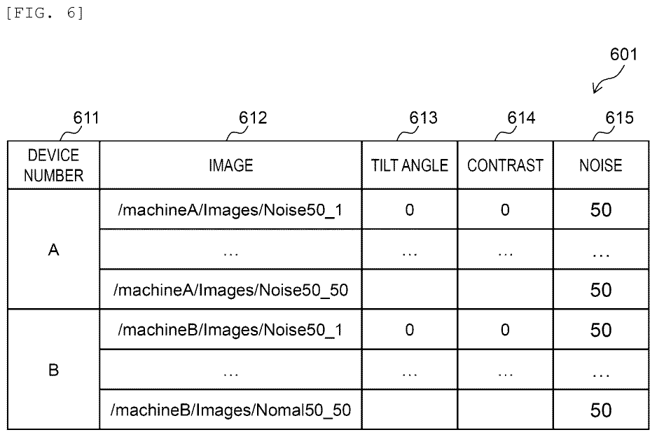

Next, in step S206, the training data generation unit 125 stores the adjusted indicator value in the training data storage unit 111 together with the image. FIG. 6 shows an example of a dataset where the image data is associated with the adjusted indicator value.

A dataset 601 in which the image data and the adjusted indicator value are associated includes a device number 611, a path 612 to the image data, a tilt angle 613 that is an analysis target indicator value, contrast 614, and noise 615. Here, the noise 615 stores a value obtained by adding a numerical value of the adjustment value corresponding to the adjusted indicator value in step S204.

Finally, in step S207, step S205 and step S206 are repeated until data acquisition is completed for all adjustment values determined in step S205.

The training data storage unit 111 stores the dataset generated by the above flow. In the device variation factor analysis device of the invention, since the model for predicting the indicator value is generated using this dataset, the device variation factor analysis from which the influence of the individual difference is removed can be performed.

Next, a function of the indicator value prediction model generation unit 122 will be described.

The indicator value prediction model generation unit 122 receives the image data from the dataset stored in the training data storage unit 111 and generates a machine learning model for predicting the corresponding indicator value.

The machine learning model outputs output data having a high possibility of corresponding to the input data according to a trend of the training dataset used for construction. Therefore, the machine learning model trained using the dataset from which the individual difference is removed stored in the training data storage unit 111 outputs the indicator value from which the influence of the individual difference is removed even in a predicted value.

In the embodiment, a convolutional neural network is assumed as a machine learning algorithm.

As in the related art, it is possible to obtain the indicator value by performing image processing on the image data or acquiring an electron microscope setting. However, the device variation factor analysis device 101 does not obtain the indicator value based on the image processing on the image data or the electron microscope setting, but generates, by machine learning, the model for predicting the indicator value upon receiving the image data.

Training data for the machine learning includes data where the same indicator value is assigned to image data whose critical dimension value falls within a predetermined range, an indicator value changed therefrom, and image data corresponding to the changed indicator value.

That is, a set of the indicator value and a plurality of pieces of image data corresponding to the indicator value is prepared for two or more values of the indicator value, and the set is used as the training data to generate the model for predicting the indicator value.

The model for predicting the indicator value may be generated for each type of the indicator value. For example, a tilt angle prediction model, a contrast prediction model, and a noise prediction model may be generated. In addition, a model that outputs a plurality of types of indicator values may be generated.

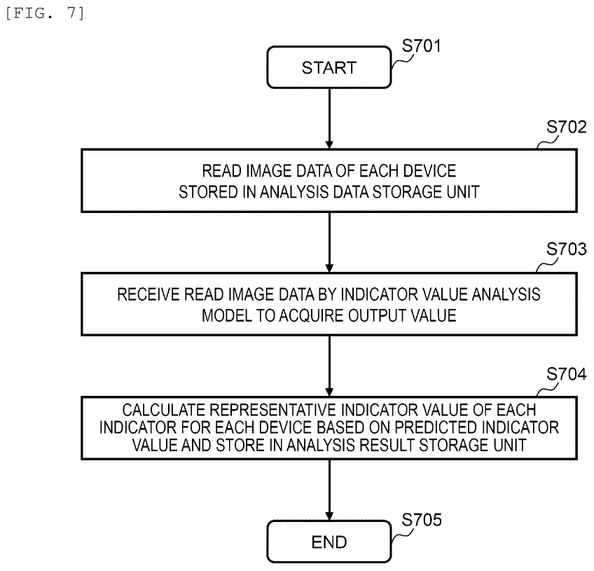

FIG. 7 shows a processing flow of the device variation factor analysis unit 123. In the following embodiment, a function of the device variation factor analysis unit 123 will be described according to this flow.

In the embodiment, a device group that is a device variation factor analysis target is referred to as a second device group.

Here, it is assumed that the analysis data storage unit 112 stores data acquired by the second device group in a format to be described later. As described above, it is desirable to use a standard wafer for the critical dimension measurement that is equivalent to the wafer used for the device variation factor analysis.

First, in step S702, the device variation factor analysis unit 123 reads a dataset from the second device group stored in the analysis data storage unit 112.

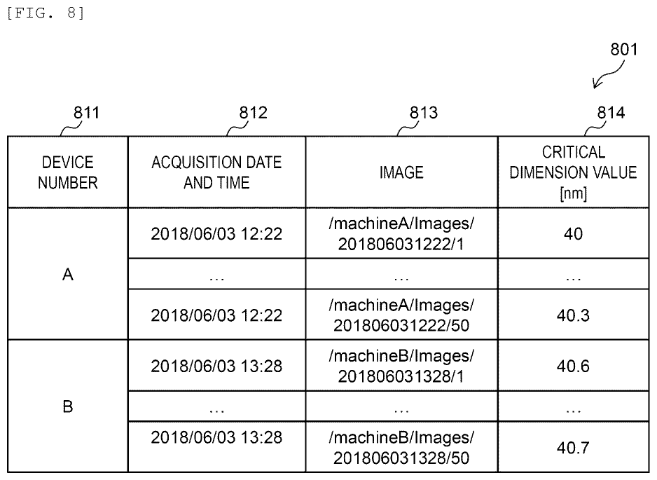

FIG. 8 shows an example of the dataset acquired from the second device group and stored in the analysis data storage unit 112.

A dataset 801 stored in the analysis data storage unit 112 includes a device number 811, a data acquisition date and time 812, a path 813 to image data, and a critical dimension value 814 that is a critical dimension measurement result.

Next, in step S703, the device variation factor analysis unit 123 inputs the read image data from each device to the indicator value prediction model and acquires an output value thereof.

Next, in step S704, the device variation factor analysis unit 123 calculates a representative indicator value of each indicator for each device based on the acquired predicted indicator value and stores the calculated representative indicator value in the analysis result storage unit 113.

In the embodiment, an average value of indicator predicted values in all images from each device is acquired as the representative indicator value of each device. Here, the method for calculating the representative indicator value is not limited to the average value, and may be a median value or the like.

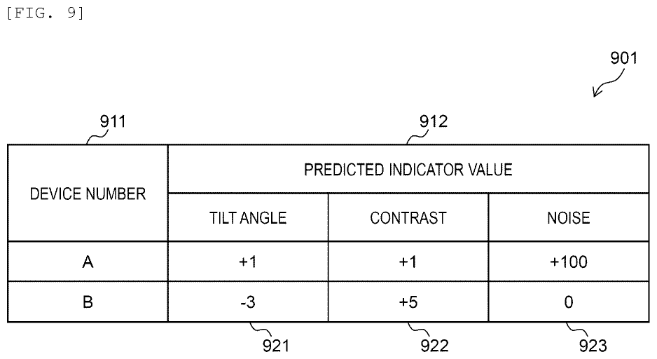

FIG. 9 shows an example of a dataset stored in the analysis result storage unit 113.

A dataset 901 stored in the analysis result storage unit 113 includes a device number 911 and a predicted indicator value 912, and the predicted indicator value 912 includes a tilt angle 921, contrast 922, and noise 923, which are analysis target indicator values.

Here, in the tilt angle 921, the contrast 922, and the noise 923, the representative indicator value of each indicator for each device calculated in step S704 is stored.

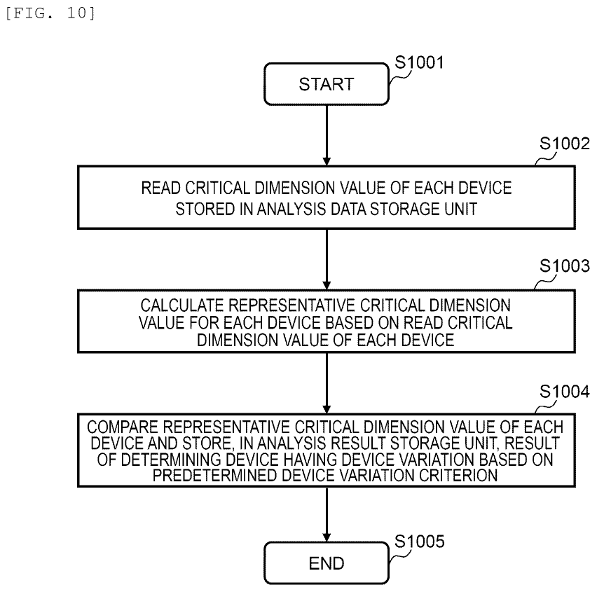

FIG. 10 shows a processing flow of the device variation determination unit 121. In the following embodiment, a function of the device variation determination unit 121 will be described according to this flow.

First, in step S1002, the device variation determination unit 121 reads the critical dimension value of each device from the dataset from the second device group stored in the analysis data storage unit 112.

Next, in step S1003, the device variation determination unit 121 calculates a representative critical dimension value for each device based on the critical dimension value of each image from each device read in step S1002. In this embodiment, an average value is used as a method for calculating the representative critical dimension value. Here, the method for calculating the representative critical dimension value is not limited to the average value, and may be a median value or the like.

Next, in step S1004, the device variation determination unit 121 compares the representative critical dimension value of each device based on a predetermined device variation criterion to determine the device having a device variation. Thereafter, this result is stored in the analysis result storage unit 113.

In the embodiment, a range where a difference from the critical dimension value of the device A is −0.1 nm to +0.1 nm, which is equivalent to the criterion used when acquiring the data stored in the training data storage unit 111, is used as the criterion.

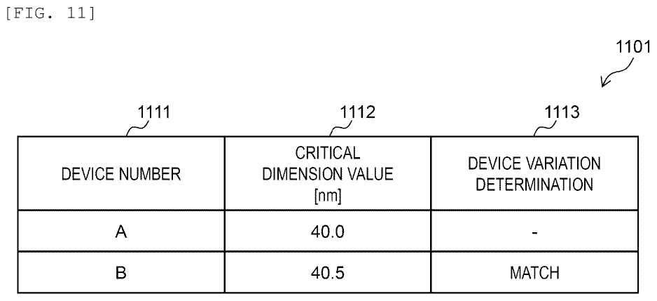

FIG. 11 shows an example of the dataset stored in the analysis result storage unit 113 by the above processing.

A dataset 1101 includes a device number 1111, a critical dimension value 1112 of each device, and a device variation determination result 1113.

Regarding the device variation determination result 1113, in the embodiment, since the range where the critical dimension value difference from the device A is −0.1 nm to +0.1 nm is used as the device variation criterion, the device A is not the device having a device variation, and the device B is the device having a device variation since the critical dimension value difference from the device A is 0.5 nm. Therefore, the device variation determination result 1113 stores device variation determination “match” only for the device B.

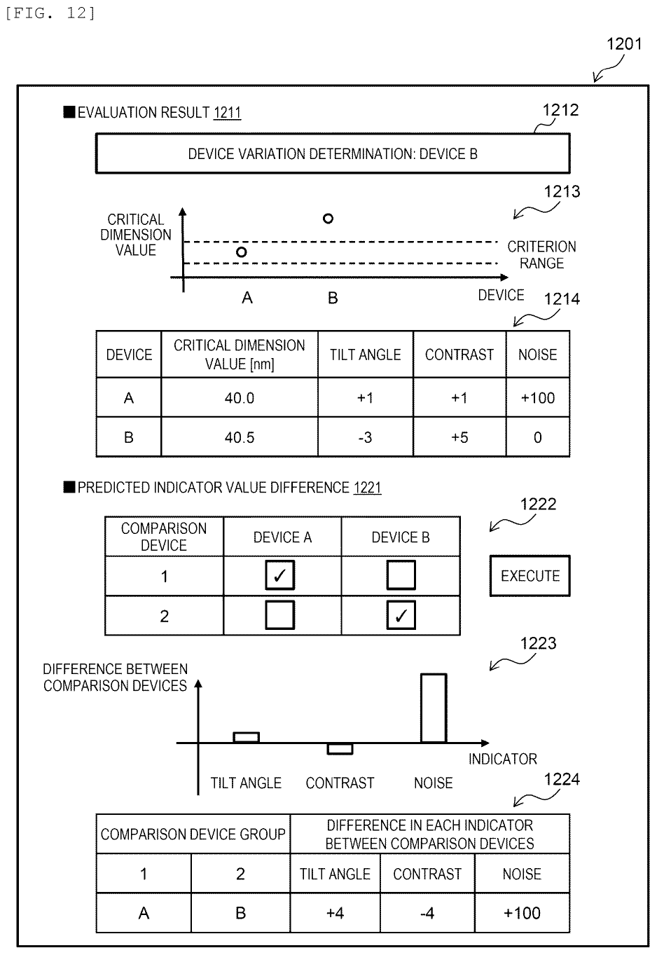

FIG. 12 shows an example of an output screen 1201 output to the input and output device 103, which is obtained by the execution of the device variation factor analysis device.

1211 that displays an evaluation result based on the dataset stored in the analysis result storage unit 113 includes 1212 that outputs the device determined to have the device variation based on the dataset in FIG. 11, a graph 1213 that visualizes the critical dimension value acquired from each device and the device variation determination criterion range based on the dataset in FIG. 11, and a table 1214 that displays the critical dimension value of each device based on the dataset in FIG. 11 and the indicator value predicted based on the dataset in FIG. 9.

1221 that displays a calculation result of a difference in the predicted indicator value based on the dataset stored in the analysis result storage unit 113 by the analysis result processing unit 124 includes a table for selecting devices to be compared, a button 1222 for executing analysis, a graph 1223 indicating, relative to comparison devices selected in 1222, an indicator value difference between the comparison devices analyzed by the analysis result processing unit 124 based on the data stored in the analysis result storage unit 113, and a table 1224 that describes the indicator value difference between the comparison devices analyzed by the analysis result processing unit 124 based on the data stored in the analysis result storage unit 113.

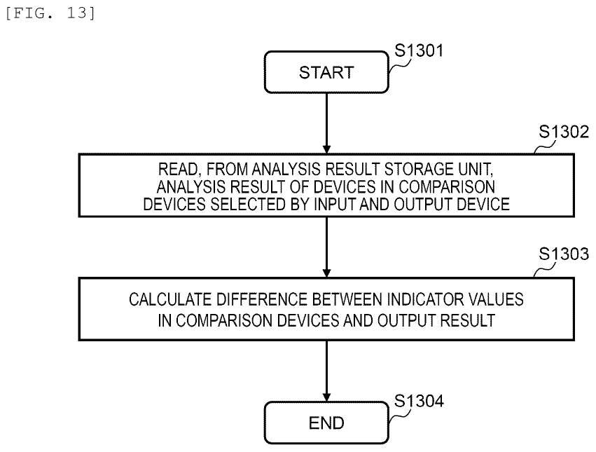

Next, FIG. 13 shows a processing flow of the analysis result processing unit 124. In the following embodiment, a function of the analysis result processing unit 124 will be described according to this flow.

First, in step S1302, the analysis result processing unit 124 reads, from the analysis result storage unit 113, the analysis result of the devices in the comparison devices selected by the input and output device. In this embodiment, since the device A is selected as a comparison device 1 and the device B is selected as a comparison device 2, a dataset thereof is read from the analysis result storage unit. That is, the dataset in FIG. 9 is read.

Next, in step S1303, the analysis result processing unit 124 calculates and outputs a difference between predicted indicator values in the comparison device 1 and the comparison device 2 based on the read dataset. In this embodiment, since the device A is selected as the comparison device 1 and the device B is selected as the comparison device 2, a difference therebetween is calculated.

Here, when a plurality of devices are selected as the comparison devices, an appropriate measure may be taken, such as acquiring an average value of predicted indicator values in the devices of the comparison devices.

### Second Embodiment

Next, a method of performing, using the device variation factor analysis device, processing for predicting a magnitude of a critical dimension value change contributed by each factor based on an indicator value predicted from data of the second device group will be described.

In the method in the first embodiment, the devices from the second device group are compared, the difference between the predicted values of the respective indicator values is calculated to determine the device variation factor, but it is not possible to determine how much the indicator value difference affects the critical dimension value. In particular, even when the indicator value difference is the same, it is assumed that an amount of change in the critical dimension value changes depending on a difference in a magnitude of the indicator value directly predicted based on the image. For example, when noise predicted values of the device A and the device B are 0 and 50 in one case, and 150 and 200 in another case, it is assumed that the amount of change in the critical dimension value differs although the difference between the predicted values is the same.

Therefore, in a device variation factor analysis device in a second embodiment, the magnitude of the critical dimension value change due to each factor is predicted based on an indicator value predicted value of each device in the second device group.

In this processing, since a magnitude of an actual critical dimension value difference can be compared with the magnitude of the critical dimension value change caused by each factor, the device variation factor can be identified with higher accuracy.

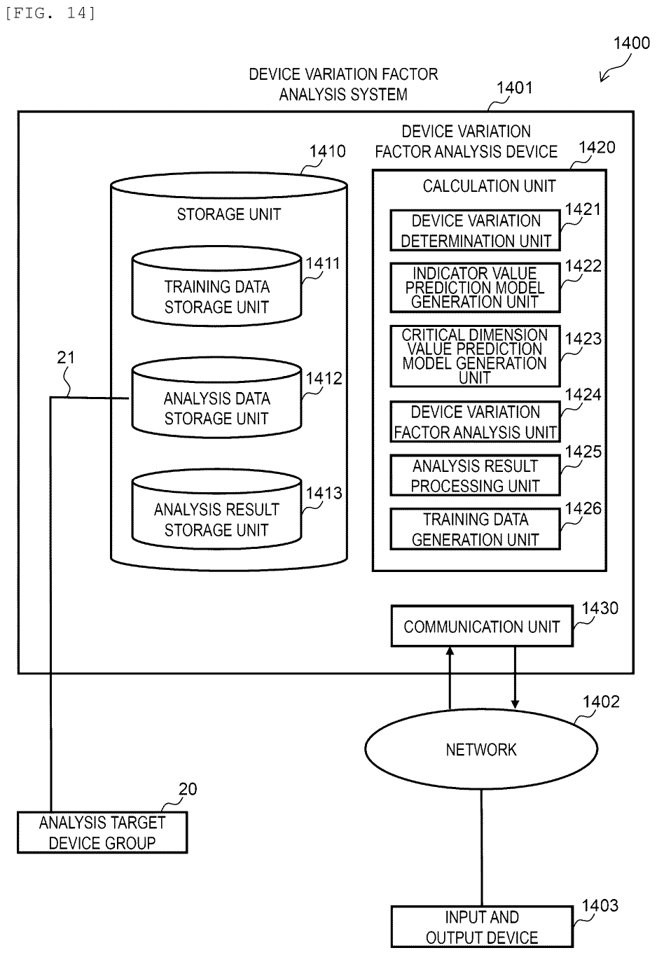

FIG. 14 shows a device variation factor analysis device 1401 and a device variation factor analysis system 1400 including a device management method according to an embodiment of the invention.

The device variation factor analysis system 1400 of the embodiment includes the device variation factor analysis device 1401 and an input and output device 1403 used by a user, which are communicably connected via a network 1402.

The network 1402 enables the input and output device 1403 and the device variation factor analysis device 1401 to communicate with each other.

The input and output device 1403 is an information processing device such as a personal computer (PC). The user inputs predetermined information to the input and output device, and the input and output device outputs a result calculated in the device variation factor analysis device. As a specific example, when it is desired to analyze a device variation factor of two devices in a certain device group, input information is device numbers to be compared, and output information is a variable that is a device variation factor candidate.

The device variation factor analysis device 1401 is a device variation factor analysis device that generates an indicator value prediction model for predicting a value of an indicator value from an image based on a dataset where an image captured by a scanning electron microscope is associated with an indicator value from which an individual difference is removed, and analyzes a device variation factor in a certain device group based on this model.

The device variation factor analysis device 1401 includes a storage unit 1410 and a calculation unit 1420.

The storage unit 1410 includes a training data storage unit 1411 that stores image data and indicator value information to be used as training data for constructing the indicator value prediction model, an analysis data storage unit 1412 that stores data to be used for analysis acquired from an analysis target device group 20, and an analysis result storage unit 1413 that stores a result calculated by device variation factor analysis.

The training data storage unit 1411 can transmit and receive data to and from the analysis target device 20 via a data bus or the Internet 21.

The calculation unit 1420 includes a device variation determination unit 1421 that calculates a critical dimension value difference based on data acquired from the analysis target device group 20 and calculates a device variation magnitude, an indicator value prediction model generation unit 1422 that constructs the indicator value prediction model based on the training data, a critical dimension value prediction model generation unit 1423 that constructs a critical dimension value prediction model based on the training data, a device variation factor analysis unit 1424 that predicts a critical dimension value of each factor in each device by inputting, to the critical dimension value prediction model, a predicted indicator value obtained by applying the indicator value prediction model to the analysis target device group, an analysis result processing unit 1425 for calculating a result of comparing analyzed results between devices, and a training data generation unit 1426 that generates the training data.

A communication unit 1430 communicates with the device variation factor analysis device 1401 and other devices via the network 1402.

The device variation factor analysis device 1401 and the device variation factor analysis system 1400 in FIG. 14 have the same configurations as those in FIG. 1 except for addition of the critical dimension value prediction model generation unit 1423.

In the embodiment, various settings such as the first device group and the second device group, which are analysis targets, and the device variation determination criterion are assumed to be in the same format as in the first embodiment. Differences will be described as necessary.

First, a dataset is stored in the training data storage unit 1411 by the same processing as in the first embodiment.

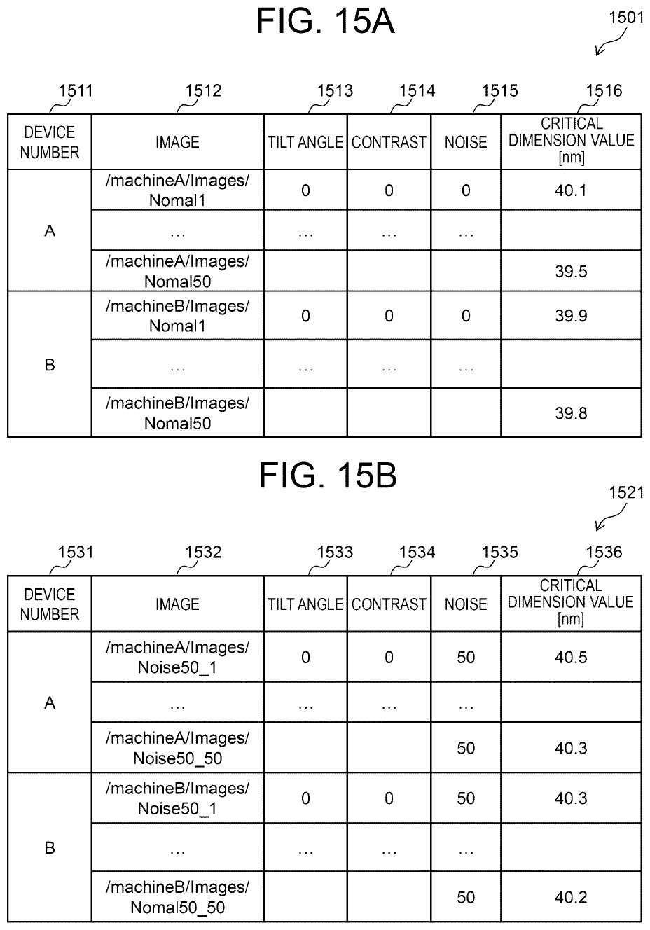

At this time, the dataset to be stored is a dataset including a critical dimension value 1516 and a critical dimension value 1536 of each image as shown in (a) and (b) in FIG. 15.

Each critical dimension value is a critical dimension value acquired from each image by a scanning electron microscope.

Next, the indicator value prediction model is constructed based on the indicator value prediction model generation unit 1422 by the same method as in the first embodiment.

The critical dimension value prediction model generation unit 1423 receives an indicator value from the dataset stored in the training data storage unit 1411 and generates the critical dimension value prediction model for predicting the critical dimension value of each factor.

In the embodiment, it is assumed that a model for predicting the critical dimension value based on the indicator value of each factor is generated. Here, the model to be generated may be one model that receives indicator values of all factors and predicts the critical dimension value for each factor.

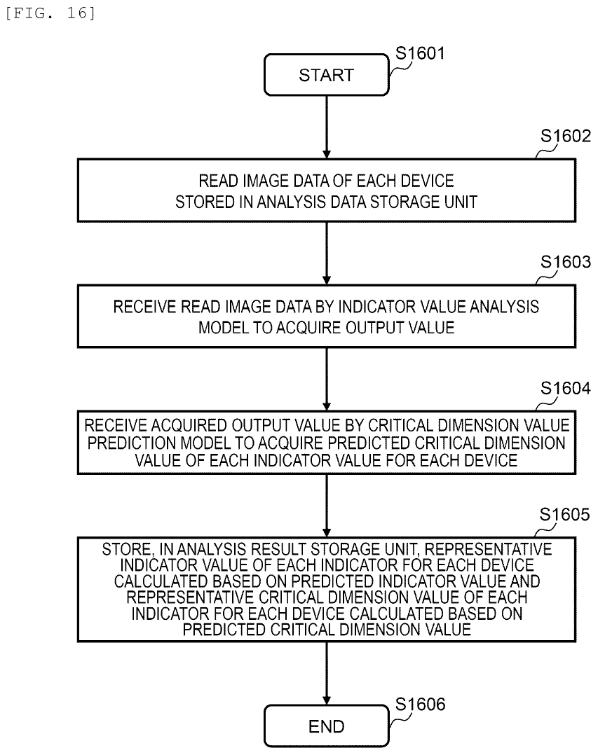

FIG. 16 shows a processing flow of the device variation factor analysis unit 1424. In the following embodiment, a function of the device variation factor analysis unit 1424 will be described according to this flow.

Here, it is assumed that the data acquired by the second device group is stored in the analysis data storage unit 1412 in the same format as in the first embodiment.

First, in step S1602, the dataset from the second device group stored in the analysis data storage unit 1412 is read in the same manner as in the first embodiment.

Next, in step S1603, the read image data from each device is received by the indicator value prediction model and an output value thereof is acquired in the same manner as in the first embodiment.

Next, in step S1604, the predicted indicator value acquired in S1603 is received by the critical dimension value prediction model, and a predicted critical dimension value of each indicator value for each device is acquired.

Next, in step S1605, a representative indicator value of each indicator for each device calculated based on the predicted indicator value acquired in S1603 and a representative critical dimension value of each indicator for each device calculated based on the predicted critical dimension value in S1604 are stored in the analysis result storage unit 1413.

In the embodiment, for each of the indicator value and the critical dimension value, an average value of predicted values acquired for each indicator in all images from each device is acquired as the representative value. Here, the method for calculating the representative value is not limited to the average value, and may be a median value or the like.

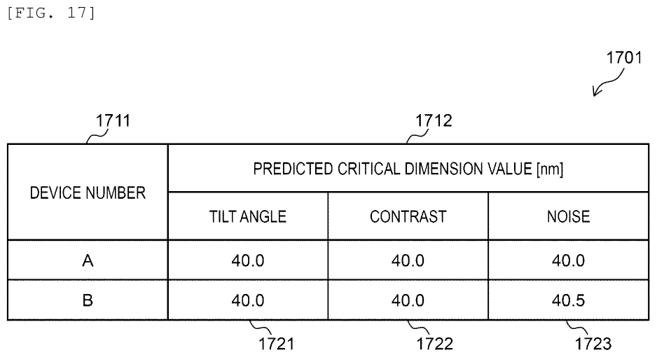

FIG. 17 shows an example of a dataset for storing the representative value of the predicted critical dimension value, which is stored in the analysis result storage unit 1413 by step S1605.

A dataset 1701 stored in the analysis result storage unit 1413 includes a device number 1711 and a predicted critical dimension value 1712, and the predicted critical dimension value 1712 includes a tilt angle 1721, contrast 1722, and noise 1723, which are analysis target indicator values.

Next, the device variation determination is performed based on the device variation determination unit 1421 using the same method as in the first embodiment.

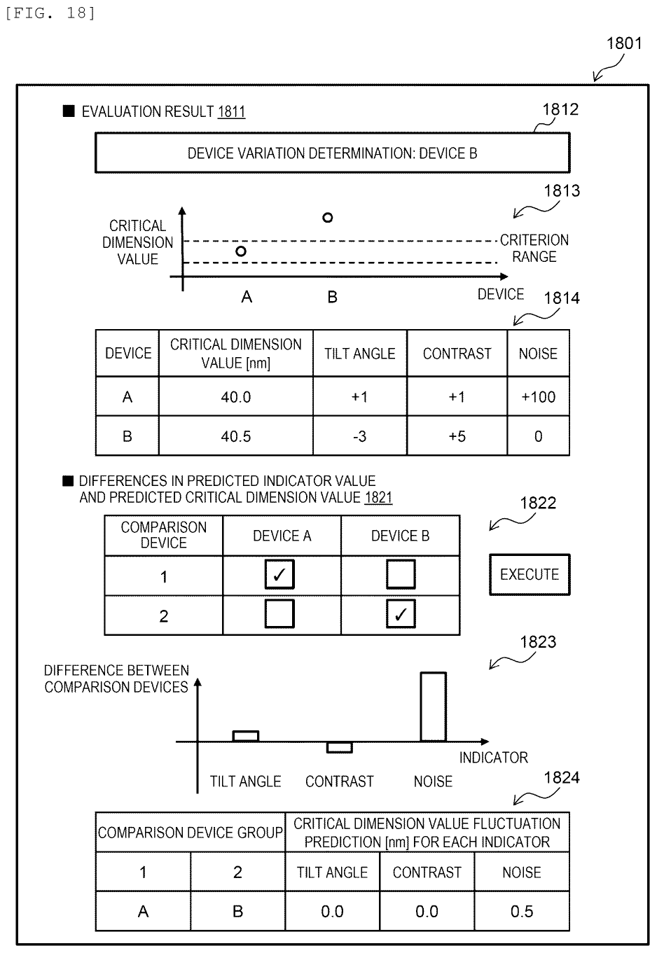

FIG. 18 shows an example of an output screen 1801 output to the input and output device 1403, which is obtained by the execution of the device variation factor analysis device.

A format is the same as that in FIG. 12 of the first embodiment except for a table 1824 where an indicator value difference and a critical dimension value difference between comparison devices analyzed by the analysis result processing unit 1425 based on the data stored in the analysis result storage unit 1413 are described, which is a constituent part of 1821 that displays a calculation result of differences in the predicted indicator value and the predicted critical dimension value based on the dataset stored in the analysis result storage unit 1413 by the analysis result processing unit 1425.

A method for calculating the indicator value difference in the analysis result processing unit 1425 for displaying the table 1824 is the same method as that in the first embodiment. A method for calculating the critical dimension value difference in the analysis result processing unit 1425 can be implemented by replacing the method for calculating the indicator value difference with the critical dimension value.

### Third Embodiment

Next, a method of performing, by the device variation factor analysis device, processing using history data of the second device group acquired in the past for generating the critical dimension value prediction model will be described.

In the method in the second embodiment, only the data stored in the training data storage unit 1411 is used for generating the critical dimension value prediction model, but it is anticipated that a combination of indicator values not contained in the data may be received at the time of device variation factor analysis, and in this case, critical dimension value prediction accuracy may decrease.

This is because, when several factors interact to cause a change, an image state changes in a composite manner, and thus it is conceivable that a magnitude of a critical dimension value fluctuation due to a certain factor differs from a case of a single factor change. Therefore, when a certain critical dimension value is predicted, in a case where a received combination of indicator values is greatly different from the data stored in the training data storage unit 1411, a magnitude of a predicted critical dimension value change thereof is different from an actual magnitude, and there is a possibility that an analyst using the device variation factor analysis device may erroneously determine the device variation factor.

Therefore, in a device variation factor analysis device of a third embodiment, through using actual past values in the second device group, a critical dimension value prediction model of each factor can be generated based on data not stored in the training data storage unit 1411.

In this processing, a possibility that the combination of indicator values to be analyzed at the time of device variation factor analysis is similar to data used as training data at the time of critical dimension value prediction model generation increases, and accuracy can be ensured.

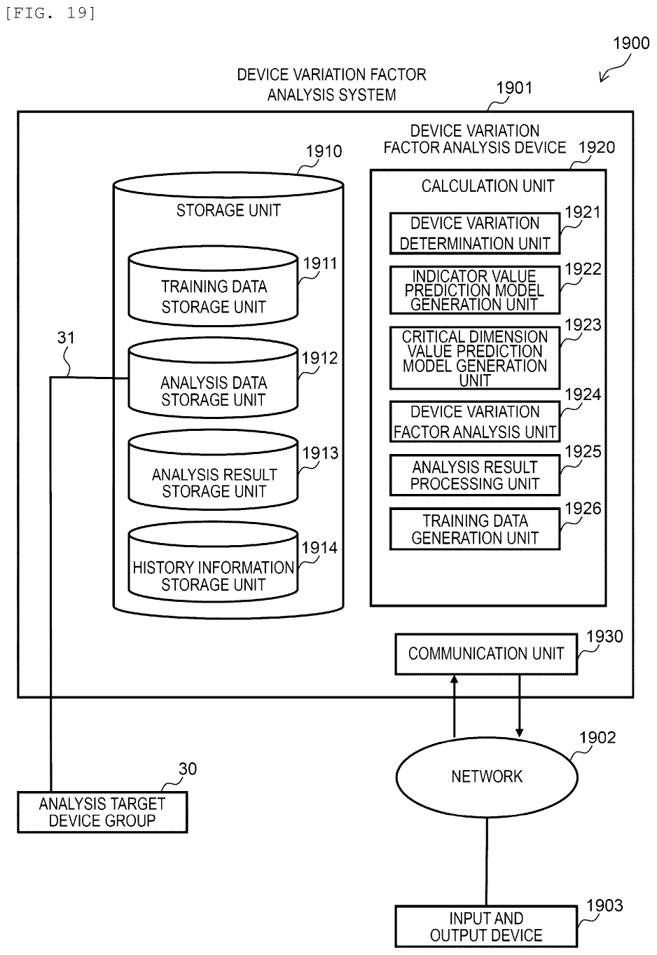

FIG. 19 shows a device variation factor analysis device 1901 and a device variation factor analysis system 1900 including a device management method according to an embodiment of the invention.

The device variation factor analysis system 1900 of the embodiment includes the device variation factor analysis device 1901 and an input and output device 1903 used by a user, which are communicably connected via a network 1902.

The network 1902 enables the input and output device 1903 and the device variation factor analysis device 1901 to communicate with each other.

The input and output device 1903 is an information processing device such as a personal computer (PC). The user inputs predetermined information to the input and output device, and the input and output device outputs a result calculated in the device variation factor analysis device. As a specific example, when it is desired to analyze a device variation factor of two devices in a certain device group, input information is device numbers to be compared, and output information is a variable that is a device variation factor candidate.

The device variation factor analysis device 1901 is a device variation factor analysis device that generates an indicator value prediction model for predicting a value of an indicator value from an image based on a dataset where an image captured by a scanning electron microscope is associated with an indicator value from which an individual difference is removed, and analyzes a device variation factor in a certain device group based on this model.

The device variation factor analysis device 1901 includes a storage unit 1910 and a calculation unit 1920.

The storage unit 1910 includes a training data storage unit 1911 that stores image data and indicator value information to be used as training data for constructing the indicator value prediction model, an analysis data storage unit 1912 that stores data to be used for analysis acquired from an analysis target device group 30, an analysis result storage unit 1913 that stores a result calculated by device variation factor analysis, and a history information storage unit 1914 that stores data where acquired data, the indicator value predicted by the indicator value prediction model, and an actually measured critical dimension value are associated.

The training data storage unit 1911 can transmit and receive data to and from the analysis target device 30 via a data bus or the Internet 31.

The calculation unit 1920 includes a device variation determination unit 1921 that calculates a critical dimension value difference based on data acquired from the analysis target device group 30 and calculates a device variation magnitude, an indicator value prediction model generation unit 1922 that constructs the indicator value prediction model based on the training data, a critical dimension value prediction model generation unit 1923 that constructs a critical dimension value prediction model based on the training data, a device variation factor analysis unit 1924 that predicts a critical dimension value of each factor in each device by inputting, to the critical dimension value prediction model, a predicted indicator value obtained by applying the indicator value prediction model to the analysis target device group, an analysis result processing unit 1925 for calculating a result of comparing analyzed results between devices, and a training data generation unit 1926 that generates the training data.

A communication unit 1930 communicates with the device variation factor analysis device 1901 and other devices via the network 1902.

The device variation factor analysis device 1901 and the device variation factor analysis system 1900 in FIG. 19 have the same configurations as those in FIG. 14 except for addition of the history information storage unit 1914.

In the embodiment, various settings such as the first device group and the second device group, which are analysis targets, and the device variation determination criterion are assumed to be in the same format as in the second embodiment. Differences will be described as necessary.

First, a dataset is stored in the training data storage unit 1911 by the same processing as in the second embodiment, and the indicator value prediction model is constructed.

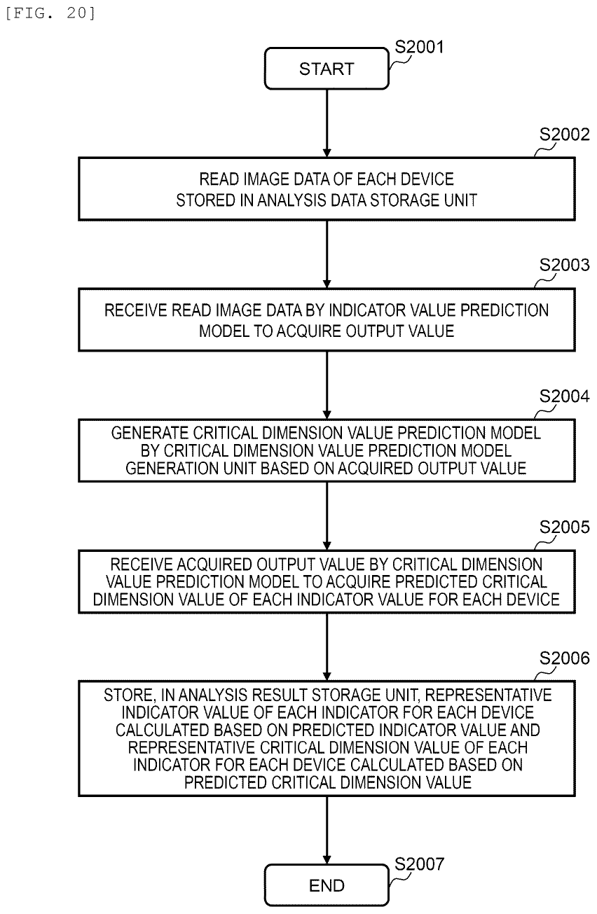

FIG. 20 shows a processing flow of the device variation factor analysis unit 1924. In the following embodiment, a function of the device variation factor analysis unit 1924 will be described according to this flow.

Here, it is assumed that the data acquired by the second device group is stored in the analysis data storage unit 1912 in the same format as in the second embodiment.

First, in step S2002 and step S2003, the dataset from the second device group stored in the analysis data storage unit 1912 is read, received by the indicator value prediction model, and an output value thereof is acquired in the same manner as in the second embodiment.

Next, in step S2004, the critical dimension value prediction model generation unit 1923 generates the critical dimension value prediction model based on the predicted indicator value acquired in step S2003.

Here, in the embodiment, it is assumed that indicator values of factors (tilt angle, contrast, and noise) predicted by the indicator value prediction model for the device A and device B in the second device group are acquired as (100, 100, 30) and (110, 100, 100), respectively.

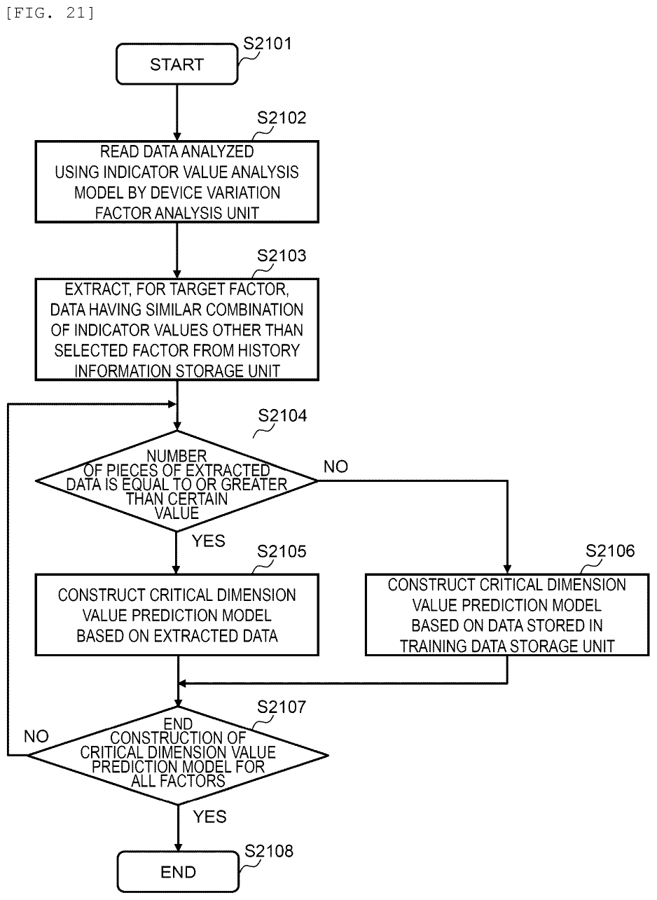

FIG. 21 shows a processing flow of the critical dimension value prediction model generation unit 1923. In the following embodiment, a function of the critical dimension value prediction model generation unit 1923 will be described according to this flow.

First, in step S2102, an indicator value prediction result calculated by the device variation factor analysis unit 1924 is read.

Next, in step S2103, one factor is selected from analysis target factors, and data having a similar combination of indicator values other than the selected factor is extracted from the history information storage unit 1914. In the embodiment, it is assumed that the noise indicator is first selected.

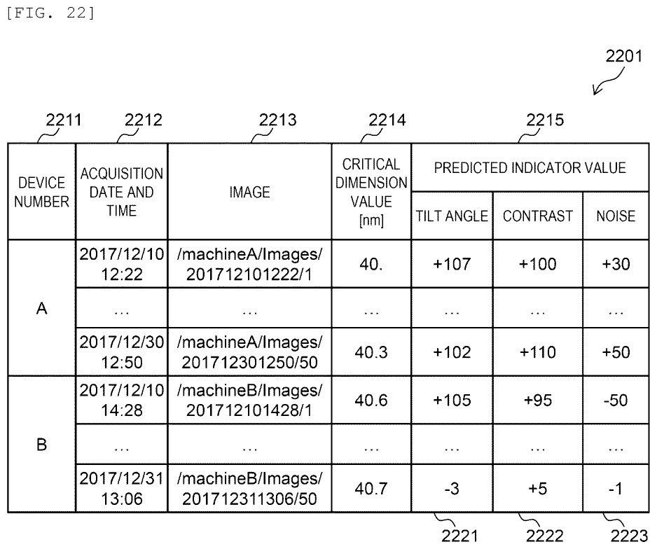

FIG. 22 shows an example of data stored in the history information storage unit 1914.

A dataset 2201 stored in the history information storage unit 1914 includes a device number 2211, an acquisition date and time 2212, a path 2213 to an image, an actual measured value 2214 of the critical dimension value, and a predicted indicator value 2215, and the predicted indicator value 2215 includes a tilt angle 2221, contrast 2222, and noise 2223 that are analysis target indicator values.

This dataset is a dataset including image data from the second device group acquired in a past operation or the like, the critical dimension value, and an indicator value prediction result acquired by analysis using the indicator value prediction model.

From the dataset, only data having a combination of indicator values other than the selected factor similar to the analysis target is extracted and used for generating the critical dimension value prediction model.

Here, regarding a definition of a similar dataset, in the embodiment, an average value is obtained for each device with respect to the indicator values other than the factor selected in step S2103, and the dataset is defined as data in a range of −10 to +10 from the average value.

That is, in the embodiment, when the critical dimension value prediction model is generated for the noise as a target, predicted indicator values of the factors (tilt angle, contrast) other than the selected factor are (100, 100), (110, 100) for the device A and device B, and thus average values thereof are calculated as (105, 100). Therefore, data having a tilt angle of −95 to +115 and contrast of −90 to +110 is regarded as similar data.

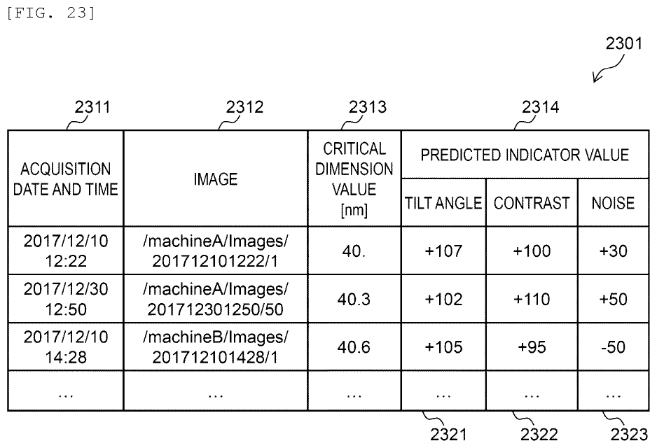

FIG. 23 shows an example of the dataset extracted in step S2103 in the embodiment.

A dataset 2301 extracted in step S2103 includes an acquisition date and time 2311, a path 2312 to an image, an actual measured value 2313 of the critical dimension value, and a predicted indicator value 2314, and the predicted indicator value 2314 includes a tilt angle 2321, contrast 2322, and noise 2323 that are analysis target indicator values.

Regarding the tilt angle 2321 and the contrast 2322, it can be seen that the indicator value is within the range set as the similarity criterion described above.

Next, in step S2104, it is determined whether the number of pieces of data extracted in step S2103 is equal to or greater than a certain value. When the number of pieces of data is small, there is a possibility that the critical dimension value prediction model cannot be appropriately generated, and thus this processing is performed for checking. In the embodiment, a criterion for the number of pieces of data is 10 or more. This criterion may be changed as appropriate, for example, by checking accuracy by experiment and finding an appropriate value.

Next, in step S2105, the critical dimension value prediction model is constructed based on the extracted data. By generating the critical dimension value prediction model by this processing, the combination of indicator values input at the time of device variation factor analysis is similar to the data used as the training data, and thus accuracy of the critical dimension value prediction model can be ensured.

When the number of pieces of extracted data is small in S2104, as described in step S2106, the critical dimension value prediction model is constructed based on the dataset stored in the training data storage unit 1911 in the same manner as in the second embodiment.

Next, in step S2107, it is determined whether the critical dimension value prediction model has been generated for all factors. When the critical dimension value prediction model is not generated for all the factors, a factor for which the model is not generated is selected in step S2103, and the processing is repeated.

The processing flow described above is the function of the critical dimension value prediction model generation unit 1923.

Next, in step S2005, the acquired predicted indicator value is received by the critical dimension value prediction model, and a predicted critical dimension value of each indicator value for each device is acquired.

Next, in step S2006, as in the second embodiment, a representative indicator value of each indicator for each device calculated based on the acquired predicted indicator value and a representative critical dimension value of each indicator for each device calculated based on the predicted critical dimension value are stored in the analysis result storage unit 1913.

Thereafter, the critical dimension value prediction model can be used for device variation factor analysis by performing the same processing as in the second embodiment.

### Fourth Embodiment

The first embodiment, the second embodiment, and the third embodiment are used for the purpose of estimating the factor of the critical dimension value difference between different devices, and may alternatively be used for the purpose of estimating an occurrence factor for a critical dimension value difference in the same device in different time series instead of between different devices.

Therefore, in an aspect in a fourth embodiment, the devices compared in FIGS. 12 and 18 are a time series of the same device.

Therefore, the analysis target device group 10 in the system configuration includes at least one scanning electron microscope device.

### Fifth Embodiment

Next, a method will be described in which the device variation factor analysis device performs processing of estimating and outputting a device variation factor candidate at the time of device variation factor analysis based on device variation factor history data of the second device group analyzed in the past.

In the method in the first embodiment, when an image similar to an image where a factor is erroneously determined before is acquired at the time of device variation factor analysis, the same erroneous determination may be caused.

Therefore, in the device variation factor analysis device according to a fifth embodiment, it is possible to estimate the device variation factor candidate by referring to a device variation factor of the image which is analyzed in the past for the second device group and where the factor is erroneously determined, and determining whether the image data is similar at the time of the device variation factor analysis.

With this processing, it is possible to prevent erroneous determination similar to the erroneous determination of the device variation factor that has occurred in the past.

A configuration of the device variation factor analysis device including the device management method in this embodiment is the same as that in FIG. 1. However, unlike the first embodiment, the analysis result storage unit 113 stores the device variation factor history data created by analyzing the second device group in the past and checking the factor by the analyst, and the device variation factor analysis unit has a function of analyzing a relationship between an image obtained from the device variation factor history data and an image obtained from the second device group.

In the embodiment, various settings such as the first device group and the second device group, which are analysis targets, and the device variation determination criterion are assumed to be in the same format as in the first embodiment. Differences will be described as necessary.

In the embodiment, a machine learning model including a neural network therein is assumed as the machine learning model used as the indicator value prediction model.

The neural network is also referred to as a multilayer perceptron, and is a technique of stacking a plurality of perceptrons in a plurality of layers to gain an ability to solve a linearly non-separable problem. Here, an intermediate layer described in the embodiment may be any of a plurality of perceptron layers used for calculating a predicted result.

Since the convolutional neural network, which is the machine learning algorithm assumed in the first embodiment, has a neural network therein, this algorithm is also assumed in the present embodiment.

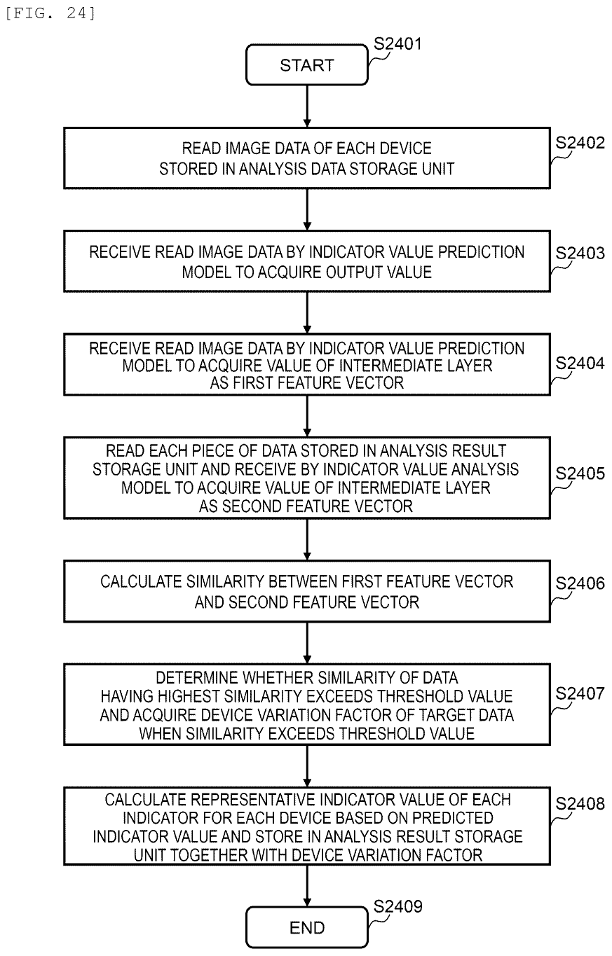

FIG. 24 shows a processing flow of the device variation factor analysis unit 123 in the embodiment. In the following embodiment, a function of the device variation factor analysis unit 123 will be described according to this flow.

In step S2402 and step S2403, similarly to the first embodiment, the dataset from the second device group stored in the analysis data storage unit 112 is read, the image data from each device is received by the indicator value prediction model, and the output value thereof is acquired.

Next, in step S2404, the read image data is received by an indicator value analysis model, and a value of the intermediate layer is acquired as a first feature vector. Here, the feature vector is assumed to be a vector obtained by receiving each image by the indicator value prediction model and averaging, across all images, values of the intermediate layer for each acquired image. That is, feature vectors in this step are calculated according to the number of second device groups. Here, the method for calculating the feature vector is not limited to averaging, and another statistic measure such as a median value may be acquired.

Next, in step S2405, the data stored in the analysis result storage unit 113 is read and input to the indicator value analysis model, and the value of the intermediate layer is acquired as a second feature vector.

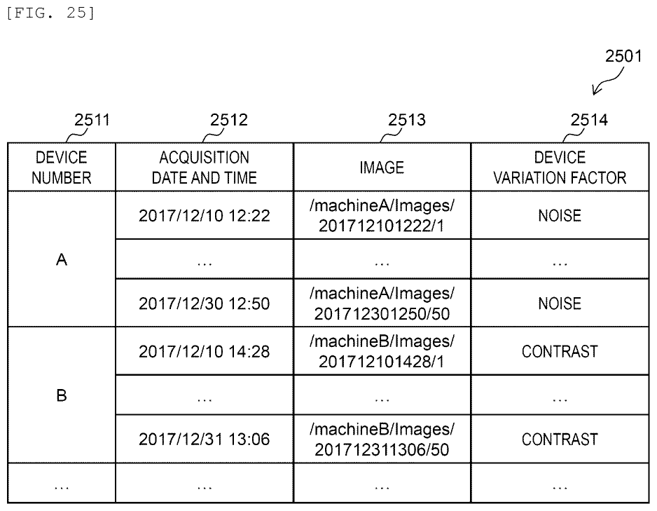

FIG. 25 shows an example of a device variation factor history dataset stored in the analysis result storage unit 113.

A dataset 2501 stored in the analysis result storage unit 113 includes a device number 2511, an acquisition date and time 2512, a path 2513 to the image data, and an actual device variation factor history 2514 determined by the analyst.

The device variation factor is assumed to be input by the analyst using the device variation factor analysis device.

The number of pieces of data read from the analysis result storage unit may be one or more. Therefore, the feature vectors in this step are calculated according to the number of pieces of data read from the analysis result storage unit.

Next, in step S2406, similarity between the first feature vector and the second feature vector is calculated.

In the embodiment, a reciprocal of a mean square error is used as vector similarity. By taking the reciprocal of the error, a greater value indicates that the vectors are more similar.

Here, as the method for calculating the similarity, cosine similarity calculated based on an angle formed by the vectors or the like may be appropriately selected.

Next, in step S2407, data having highest similarity is selected from the data stored in the analysis result storage unit 113, and it is determined whether the similarity exceeds a set threshold value. When the similarity exceeds the threshold value, a device variation factor of the target data is acquired.

Here, in the embodiment, the threshold value for the similarity is 0.5. The threshold value may be changed as appropriate.

In the embodiment, it is assumed that, an image from the device B has highest similarity to data where the device variation factor is the contrast in the device variation factor history dataset stored in the analysis result storage unit 113, and the similarity of the feature vector exceeds the threshold value. In addition, it is assumed that there is no image similar to an image from the device A in the device variation factor history dataset stored in the analysis result storage unit 113.

Finally, in step S2408, the representative indicator value of each indicator for each device is calculated based on the predicted indicator value using the same method as in the first embodiment, and is stored in the analysis result storage unit 113 together with the device variation factor acquired in S2407.

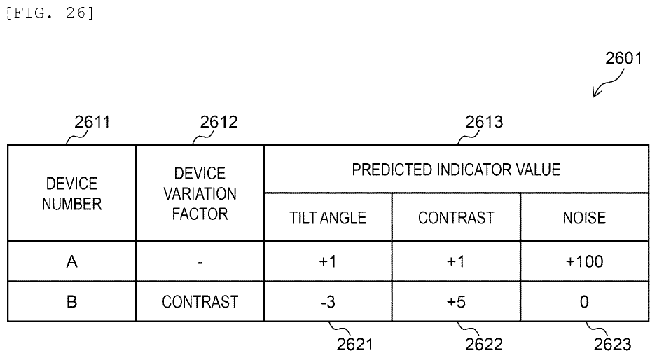

FIG. 26 shows an example of the dataset stored in the analysis result storage unit 113 by the above processing.

A dataset 2601 stored in the analysis result storage unit 113 includes a device number 2611, a device variation factor 2612, and a predicted indicator value 2613, and the predicted indicator value 2613 includes a tilt angle 2621, contrast 2622, and noise 2623, which are analysis target indicator values.

By outputting the stored result to the input and output device, the device variation factor candidate can be estimated based on a device variation factor history of an image analyzed in the past in the second device group at the time of device variation factor analysis.

As described above, the disclosed system is a device management system for managing a device that captures an image of a wafer and outputs a critical dimension value of a pattern, the device management system including: a training data generation unit (125, 1426, 1926) configured to generate training data including a first training dataset and a second training dataset; and an indicator value prediction model generation unit (122, 1422, 1922) configured to generate, using the first training dataset and the second training dataset, an indicator value prediction model that outputs a predicted indicator value for a predetermined indicator indicating a state of received image data. The training data generation unit generates the first training dataset by associating the same first indicator value with a plurality of pieces of first image data obtained by capturing images of a first wafer with devices in a first device group where a critical dimension value difference for the same wafer is equal to or less than a predetermined reference value, and adjusts the devices in the first device group such that an indicator value is changed by a predetermined value from the first indicator value, and then generates the second training dataset by associating a second indicator value, which is a value changed by the predetermined value from the first indicator value, with a plurality of pieces of second image data obtained by capturing images of the first wafer with the devices after adjustment.

In this way, by generating the indicator value prediction model by assigning the same indicator value to image data where the critical dimension value falls within a predetermined range, the plurality of devices can be managed with the indicator value without being affected by an individual difference between the devices.

The indicator is an indicator that is a potential device variation factor, and includes any one of a tilt angle indicator representing an angle of an electron beam from the device that is a scanning electron microscope, a contrast indicator representing brightness and darkness contrast of image data, and a noise indicator quantifying an amount of noise contained in the image data.

In this way, the disclosed system can eliminate an influence of an individual difference on a scanning electron microscope and obtain the indicator that may be the factor of the device variation.

The training data generation unit calculates the indicator value based on the first image data, corrects the calculated indicator value for each type of the indicator such that the indicator value has the same value in the first device group, and sets the corrected indicator value as the first indicator value.

Therefore, the indicator value for the training data can be obtained using the indicator value calculated based on the first image data.

The disclosed system further includes: a device variation factor analysis unit (123, 1424, 1924) configured to acquire, from each second device group, the second image data obtained by capturing images of a second wafer and analyze a device variation factor based on the predicted indicator value output by receiving the second image data by the indicator value prediction model; and an analysis result processing unit (124, 1425, 1925) configured to output an analysis result of the device variation factor.

According to this configuration, the disclosed system can analyze the device variation factor without being affected by the individual difference to output an analysis result.

The disclosed system further includes: a critical dimension value prediction model generation unit (1423, 1923) configured to generate, using a third training dataset where the first indicator value and a critical dimension value of the first image data are associated, a critical dimension value prediction model that receives the predicted indicator value and outputs a predicted critical dimension value. The device variation factor analysis unit estimates an indicator that is a factor of a device variation, based on the predicted critical dimension value output by receiving the predicted indicator value based on the second image data by the critical dimension value prediction model.

According to this configuration, the disclosed system can predict the critical dimension value without being affected by the individual difference to analyze the device variation factor.

The critical dimension value prediction model generation unit refers to history data where the predicted indicator value and the critical dimension value based on the second image data are associated, and uses, as the third training dataset, data having a similar condition except for the indicator to be predicted.

Therefore, even when a plurality of factors are related, the device variation factor can be analyzed with high accuracy.

The device variation factor analysis unit estimates, based on image data obtained by capturing images of the second wafer with a single device at different time points, an indicator that is a factor candidate for a critical dimension value difference in a time series.

Therefore, it is possible to estimate a factor of the critical dimension value difference due to a change over time.

The device variation factor analysis unit acquires image data when a device variation factor is erroneously determined and information on a registered device variation factor, and estimates an indicator that is a candidate for the device variation factor based on a relationship between the image data and the second image data.

Therefore, it is possible to reflect a past determination error to improve device variation factor analysis accuracy.

The invention is not limited to the above-described embodiments, and includes various modifications. For example, the above-described embodiments have been described in detail to facilitate understanding of the invention, and the invention is not necessarily limited to those including all the configurations described above. In addition to deletion of a configuration, it is also possible to replace the configuration or add a configuration.

### REFERENCE SIGNS LIST

10, 20, 30: analysis target device group
11, 21, 31: Internet
100, 1400, 1900: device variation factor analysis system
101, 1401, 1901: device variation factor analysis device
102, 1402, 1902: network
103, 1403, 1903: input and output device
110, 1410, 1910: storage unit
111, 1411, 1911: training data storage unit
112, 1412, 1912: analysis data storage unit
113, 1413, 1913: analysis result storage unit
120, 1420, 1920: calculation unit
121, 1421, 1921: device variation determination unit
122, 1422, 1922: indicator value prediction model generation unit
123, 1424, 1924: device variation factor analysis unit
124, 1425, 1925: analysis result processing unit
125, 1426, 1926: training data generation unit
1423, 1923: critical dimension value prediction model generation unit

1. A device management system for managing a device that captures an image of a wafer and outputs a critical dimension value of a pattern, the device management system comprising:
a training data generation unit configured to generate training data including a first training dataset and a second training dataset; and
an indicator value prediction model generation unit configured to generate, using the first training dataset and the second training dataset, an indicator value prediction model that outputs a predicted indicator value for a predetermined indicator indicating a state of received image data, wherein
the training data generation unit
generates the first training dataset by associating a same first indicator value with a plurality of pieces of first image data obtained by capturing images of a first wafer with devices in a first device group where a critical dimension value difference for a same wafer is equal to or less than a predetermined reference value, and
adjusts the devices in the first device group such that an indicator value is changed by a predetermined value from the first indicator value, and then generates the second training dataset by associating a second indicator value, which is a value changed by the predetermined value from the first indicator value, with a plurality of pieces of second image data obtained by capturing images of the first wafer with the devices after adjustment.

2. The device management system according to claim 1, wherein
the indicator is an indicator that is a potential device variation factor, and includes any one of a tilt angle indicator representing an angle of an electron beam from the device that is a scanning electron microscope, a contrast indicator representing brightness and darkness contrast of image data, and a noise indicator quantifying an amount of noise contained in the image data.

3. The device management system according to claim 1, wherein
the training data generation unit calculates the indicator value based on the first image data, corrects the calculated indicator value for each type of the indicator such that the indicator value has the same value in the first device group, and sets the corrected indicator value as the first indicator value.

4. The device management system according to claim 1, further comprising:
a device variation analysis unit configured to acquire, from each second device group, the second image data obtained by capturing images of a second wafer and analyze a device variation factor based on the predicted indicator value output by receiving the second image data by the indicator value prediction model; and
an analysis result processing unit configured to output an analysis result of the device variation factor.

5. The device management system according to claim 4, further comprising:
a critical dimension value prediction model generation unit configured to generate, using a third training dataset where the first indicator value and a critical dimension value of the first image data are associated, a critical dimension value prediction model that receives the predicted indicator value and outputs a predicted critical dimension value, wherein
the device variation factor analysis unit estimates an indicator that is a factor of a device variation, based on the predicted critical dimension value output by receiving the predicted indicator value based on the second image data by the critical dimension value prediction model.

6. The device management system according to claim 5, wherein
the critical dimension value prediction model generation unit refers to history data where the predicted indicator value and the critical dimension value based on the second image data are associated, and uses, as the third training dataset, data having a similar condition except for the indicator to be predicted.

7. The device management system according to claim 4, wherein
the device variation factor analysis unit estimates, based on image data obtained by capturing images of the second wafer with a single device at different time points, an indicator that is a factor candidate for a critical dimension value difference in a time series.

8. The device management system according to claim 4, wherein
the device variation factor analysis unit acquires image data when a device variation factor is erroneously determined and information on a registered device variation factor, and estimates an indicator that is a candidate for the device variation factor based on a relationship between the image data and the second image data.

9. A device management method for managing a device that captures an image of a wafer and outputs a critical dimension value of a pattern, the device management method comprising:
causing a device management system to execute
a training data generation step of generating training data including a first training dataset and a second training dataset, and
an indicator value prediction model generation step of generating, using the first training dataset and the second training dataset, an indicator value prediction model that outputs a predicted indicator value for a predetermined indicator indicating a state of received image data, wherein
the training data generation step includes
generating the first training dataset by associating a same first indicator value with a plurality of pieces of first image data obtained by capturing images of a first wafer with devices in a first device group where a critical dimension value difference for a same wafer is equal to or less than a predetermined reference value, and
adjusting the devices in the first device group such that an indicator value is changed by a predetermined value from the first indicator value, and then generating the second training dataset by associating a second indicator value, which is a value changed by the predetermined value from the first indicator value, with a plurality of pieces of second image data obtained by capturing images of the first wafer with the devices after adjustment.
